(19) United States
(12) Patent Application Publication
(10) Pub. No.: US 2022/0413464 A1
(43) Pub. Date: Dec. 29, 2022

(54) REGISTERING OBJECTS

(71) Applicant: Hewlett-Packard Development Company, L.P., Spring, TX (US)

(72) Inventors: Jun ZENG, Palo Alto, CA (US); He LUAN, Palo Alto, CA (US); Juan Carlos CATANA SALAZAR, San Diego, CA (US)

(73) Assignee: Hewlett-Packard Development Company, L.P., Spring, TX (US)

(21) Appl. No.: 17/774,806

(22) PCT Filed: Dec. 5, 2019
(86) PCT No.: PCT/US2019/064719

§ 371 Date: May 5, 2022

(51) Int. Cl. G05B 19/4099; G06T 19/20; B33Y 50/00; B29C 64/386; B22F 10/80

(52) U.S. Cl. CPC G05B 19/4099; G06T 19/20; B33Y 50/00; B29C 64/386; B22F 10/80; G06T 2210/12; G06T 2219/2004; G06T 2210/21; G06T 2219/2016; G05B 2219/49023

(57) ABSTRACT

Examples of methods for registering objects are described herein. In some examples, a method includes determining a set of overlap scores based on a set of orientations between a first bounding box of a three-dimensional (3D) object model and a second bounding box of a 3D scan of an object. In some examples, the method includes registering the 3D scan with the 3D object model based on the set of overlap scores.

### BACKGROUND

Three-dimensional (3D) solid parts may be produced from a digital model using additive manufacturing. Additive manufacturing may be used in rapid prototyping, mold generation, mold master generation, and short-run manufacturing. Additive manufacturing involves the application of successive layers of build material. This is unlike some machining processes that often remove material to create the final part. In some additive manufacturing techniques, the build material may be cured or fused.

### BRIEF DESCRIPTION OF THE DRAWINGS

FIG. 1 is a flow diagram illustrating an example of a method for registering objects;

FIG. 2 is a flow diagram illustrating another example of a method for registering objects;

FIG. 3 is a block diagram of an example of an apparatus that may be used in registering objects;

FIG. 4 is a block diagram illustrating an example of a computer-readable medium for registering objects;

FIG. 5A is a diagram illustrating an example of a 3D object model;

FIG. 5B is a diagram illustrating an example of a 3D scan of an object;

FIG. 5C is a diagram illustrating an example of a 3D object model from FIG. 5A overlapped with the scan of the 3D object from FIG. 5B;

FIG. 6A is a diagram illustrating an example of the scan of the 3D object from FIG. 5B at an orientation relative to the 3D object model from FIG. 5A;

FIG. 6B is a diagram illustrating an example of the scan of the 3D object from FIG. 5B at an orientation relative to the 3D object model from FIG. 5A; and

FIG. 6C is a diagram illustrating an example of the scan of the 3D object from FIG. 5B at an orientation relative to the 3D object model from FIG. 5A.

### DETAILED DESCRIPTION

Additive manufacturing may be used to manufacture three-dimensional (3D) objects. 3D printing is an example of additive manufacturing. For example, thermal energy may be projected over material in a build area, where a phase change and solidification in the material may occur at certain voxels. A voxel is a representation of a location in a 3D space (e.g., a component of a 3D space). For instance, a voxel may represent a volume that is a subset of the 3D space. In some examples, voxels may be arranged on a 3D grid. For instance, a voxel may be cuboid or rectangular prismatic in shape. In some examples, voxels in the 3D space may be uniformly sized or non-uniformly sized. Examples of a voxel size dimension may include 25.4 millimeters (mm)/150≈170 microns for 150 dots per inch (dpi), 490 microns for 50 dpi, 2 mm, 4 mm, etc. The term “voxel level” and variations thereof may refer to a resolution, scale, or density corresponding to voxel size.

In some examples of additive manufacturing, thermal energy may be utilized to fuse material (e.g., particles, powder, etc.) to form an object. The manufactured object geometry may be driven by the fusion process, which enables predicting or inferring the geometry following manufacturing. Some first-principle-based manufacturing simulation approaches are relatively slow, complicated, and/or may not provide target resolution (e.g., sub-millimeter resolution). Some machine learning approaches (e.g., some deep learning approaches) may offer improved resolution and/or speed. Some machine learning approaches may utilize training data to predict or infer manufactured object deformation. The training data may indicate deformation that has occurred during a manufacturing process. For example, object deformation may be assessed based on a 3D object model (e.g., computer aided drafting (CAD) model) and a 3D scan of an object that has been manufactured based on the 3D object model. The object deformation assessment (e.g., the 3D object model and the 3D scan) may be utilized as a ground truth for machine learning. For instance, the object deformation assessment may enable deformation prediction and/or compensation. In order to assess object deformation, the 3D object model and the 3D scan may be registered. Registration is a procedure to align objects. For example, a 3D scan of an object may be registered with a 3D object model.

Some approaches to registration may attempt to align two geometric objects using a random point selection. The accuracy of those approaches may rely on the point selection quality. Moreover, such approaches are non-deterministic.

Some examples of the techniques described herein may provide approaches for 3D registration based on geometrical properties of objects. For instance, a deterministic registration may be performed. The registration may then be refined.

In some examples, the techniques described herein may be utilized for various examples of additive manufacturing. For instance, some examples may be utilized for plastics, polymers, semi-crystalline materials, metals, etc. Some additive manufacturing techniques may be powder-based and driven by powder fusion. Some examples of the approaches described herein may be applied to area-based powder bed fusion-based additive manufacturing, such as Stereolithography (SLA), Multi-Jet Fusion (MJF), Metal Jet Fusion, metal binding printing, Selective Laser Melting (SLM), Selective Laser Sintering (SLS), liquid resin-based printing, etc. Some examples of the approaches described herein may be applied to additive manufacturing where agents carried by droplets are utilized for voxel-level thermal modulation.

Throughout the drawings, identical or similar reference numbers may designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

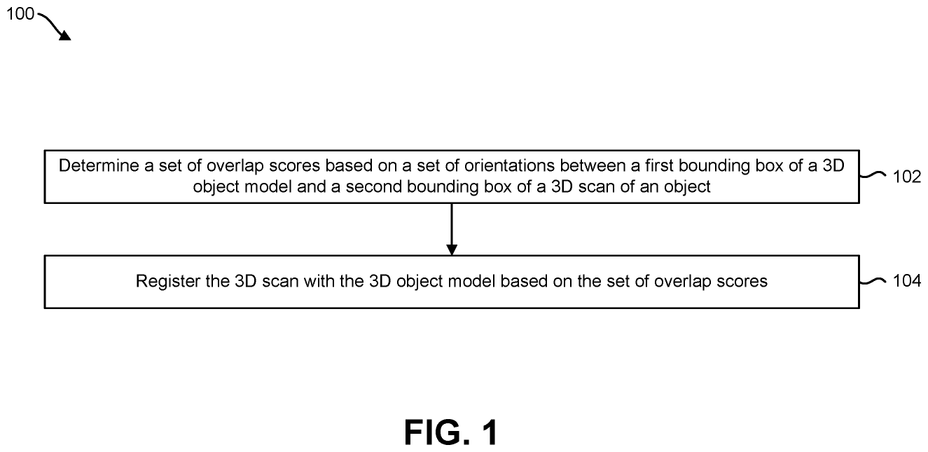

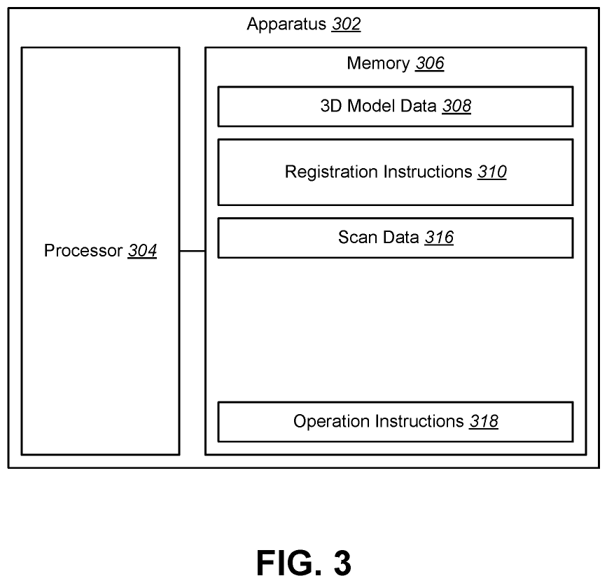

FIG. 1 is a flow diagram illustrating an example of a method 100 for registering objects. The method 100 and/or an element or elements of the method 100 may be performed by an apparatus (e.g., electronic device). For example, the method 100 may be performed by the apparatus 302 described in connection with FIG. 3.

The apparatus may determine 102 a set of overlap scores based on a set of orientations between a first bounding box of a 3D object model and a second bounding box of a 3D scan of an object. A 3D object model is a 3D geometrical model of an object. Examples of 3D object models include CAD models, mesh models, 3D surfaces, etc. In some examples, a 3D object model may be utilized to manufacture (e.g., print) an object. In some examples, the apparatus may receive a 3D object model from another device (e.g., linked device, networked device, removable storage, etc.) or may generate the 3D object model.

A 3D scan of an object is data corresponding to a physical object in 3D. For example, a scanning device (e.g., camera(s), depth sensor(s), LIDAR, etc.) may be utilized to scan a physical object in 3D. A 3D scan may be expressed as a point cloud, depth map, mesh, etc. In some examples, the apparatus may receive a 3D scan or scans of an object or objects from another device (e.g., linked device, networked device, removable storage, etc.) or may capture the 3D scan.

A bounding box is a geometrical shape that bounds (e.g., includes) an object. For example, a bounding box may be a cuboid, rectangular prism, 3D polygon, etc. One type of bounding box is a minimum bounding box. A minimum bounding box is a smallest volume or smallest size cuboid that encloses an object. A minimum bounding box may or may not be unique and/or may or may not be parallel to an axis in a 3D space. In some examples, the apparatus may determine the first bounding box of the 3D object model. For instance, the apparatus may determine dimensions of the 3D object model (e.g., minimum and maximum X-axis coordinates, minimum and maximum Y-axis coordinates, and minimum and maximum Z-axis coordinates) and may determine a cuboid (e.g., a cuboid with minimum dimensions) that encloses the dimensions of the 3D object model. In some examples, the apparatus may determine the second bounding box of the 3D scan of the object. For instance, the apparatus may determine dimensions of the 3D scan (e.g., minimum and maximum X-axis coordinates, minimum and maximum Y-axis coordinates, and minimum and maximum Z-axis coordinates) and may determine a cuboid (e.g., a cuboid with minimum dimensions) that encloses the dimensions of the 3D scan. In some examples, the apparatus may determine multiple bounding boxes for multiple objects, shapes, and/or scans. For instance, the apparatus may determine dimensions of the objects, shapes, and/or scans (e.g., minimum and maximum X-axis coordinates, minimum and maximum Y-axis coordinates, and minimum and maximum Z-axis coordinates) and may determine cuboids (e.g., cuboids with minimum dimensions) that respectively enclose the dimensions of the objects, shapes, and/or scans.

An orientation is a directionality or rotational position for a shape or object in 3D space. For example, orientations may be expressed as rotations, quaternions, rotation matrices, vectors, etc. A set of orientations is a plurality of orientations that may be applied to an object (e.g., a 3D scan of an object and/or a 3D object model). In some examples, the orientations may be expressed and/or applied as a set of X, Y, and/or Z rotations to determine a rough alignment or alignments. In some examples, the set of orientations may include orthogonal angle rotations for an axis or axes. For instance, the set of orientations may include rotations of 0 degrees (0°), 90°, 180°, and 270° for the X axis, 0°, 90°, 180°, and 270° for the Y axis, and 90° and 270° for the Z axis. Accordingly, the set of rotations may include 24 rotations in some examples. For instance, a bounding box may have 6 faces, where 4 rotations are applied to each face to provide 6×4=24 rotations. In some examples, a first set of rotations may be given by rotating 0°, 90°, 180°, and 270° for the Y axis, and for each Y-axis rotation, rotating 0°, 90°, 180°, and 270° for the X axis (4×4=16 rotations). A second set of rotations may be obtained by rotating 90° and 270° for the Z axis, and for each Z-axis rotation, rotating 0°, 90°, 180°, and 270° in the X axis (4×2=8 rotations). This may provide 24 rotations in total. In some examples, more or fewer rotations may be included in the orientations. For instance, a set of orientations may include 45° rotations for an axis or axes. In some examples, the set of orientations may be limited. For instance, the set of orientations may include less than or equal to 12, 20, 24, 30, 32, 40, 48, 50, 70, or 100 orientations, etc. In some examples, the apparatus may apply the set of orientations to the 3D scan of the object and/or to the 3D object model. For instance, the apparatus may apply the rotations of each orientation to the 3D scan.

An overlap score is a value that indicates an amount of overlap between objects and/or shapes. For example, the apparatus may superimpose (e.g., center) the first bounding box and the second bounding box at an origin of a coordinate system and determine an amount of overlap between the first bounding box and second bounding box and/or between the 3D object model and the 3D scan.

In some examples, the apparatus may determine a set of overlap scores based on the set of orientations. For instance, each overlap score of the set of overlap scores may correspond to an orientation of the set of orientations. In some examples, an overlap score may be determined based on an overlap between the first bounding box and the second bounding box at an orientation. For instance, the apparatus may apply an orientation to the second bounding box and determine the overlap between the first bounding box and the seconding bounding box at that orientation. The orientation may be applied with or without the 3D scan (or the 3D object model) corresponding to the bounding box. In some examples, an overlap score may be determined based on an overlap between the 3D object model and the 3D scan at an orientation. For instance, the apparatus may apply an orientation to the 3D scan and determine the overlap between the 3D object model and the 3D scan at that orientation.

In some examples, determining an overlap score may include calculating an intersection ratio. An intersection ratio is a ratio of an intersection of objects or shapes to a union of the objects or shapes. In some examples, the apparatus may calculate an intersection ratio by calculating a volume of an intersection of bounding boxes (e.g., of the first bounding box and the second bounding box) divided by a volume of a union of the bounding boxes (e.g., of the first bounding box and the second bounding box). In some examples, the apparatus may calculate an intersection ratio by calculating a volume of an intersection of objects (e.g., of the 3D object model and the 3D scan) divided by a volume of a union of the objects (e.g., of the 3D object model and the 3D scan). The intersection ratio may be an example of the overlap score.

The apparatus may register 104 the 3D scan with the 3D object model based on the set of overlap scores. For example, the apparatus may align the 3D scan with the 3D object model based on a candidate orientation or candidate orientations indicated by the overlap scores. A candidate orientation is an orientation that satisfies a selection criterion or criteria. For example, registering 104 the 3D scan with the 3D object model may include selecting a candidate orientation or candidate orientations based on the set of overlap scores. In some examples, a selection criterion may be a threshold (e.g., 75%, 80%, 85%, 90%, 95%, 97%, 0.75, 0.8, 0.85, 0.9, 0.95, 0.97, etc.) for the overlap scores. For instance, the apparatus may compare the overlap scores with the threshold to select a candidate orientation or candidate orientations. For example, the apparatus may select a candidate orientation or candidate orientations having a corresponding overlap score (e.g., intersection ratio) of 95% or greater.

In some examples, registering 104 the 3D scan with the 3D object model may include performing local alignment based on the candidate orientation or candidate orientations. For example, the apparatus may perform local alignment between the 3D scan and the 3D object model starting from the candidate orientation or candidate orientations. Local alignment is a procedure for aligning objects or shapes within a local range. For instance, local alignment may provide a local range of alignment or transformation that is smaller than the range of orientations in the set of orientations. In some examples, the apparatus may select a local alignment that most closely matches the 3D scan with the 3D object model. The locally aligned 3D scan and 3D object model (at the selected local alignment, for instance) may be an example of the registered 3D scan with the 3D object model.

In some examples, performing local alignment may include performing an iterative closest point (ICP) procedure between the 3D scan and the 3D object. For instance, the ICP procedure may transform the 3D scan to reduce or minimize distance between the 3D scan and the 3D object. In some examples, the ICP procedure may reduce or minimize a sum of squared errors (e.g., differences) of paired coordinate points between the 3D scan and the 3D object.

In some examples, the apparatus may provide the registered 3D scan and 3D object model. For instance, the apparatus may store the registered 3D scan and 3D object model, may send the registered 3D scan and 3D object model to another device, and/or may present the registered 3D scan and 3D object model (on a display and/or in a user interface, for example). In some examples, the apparatus may utilize the registered 3D scan and 3D object model to assess a deformation between the registered 3D scan and the 3D object model. For instance, the apparatus may determine a mean deformation and/or standard deviation (e.g., geometrical differences) between the 3D scan and the 3D object model. In some examples, the apparatus may train a machine learning model using the registered 3D scan and 3D object model deformation assessment as a ground truth.

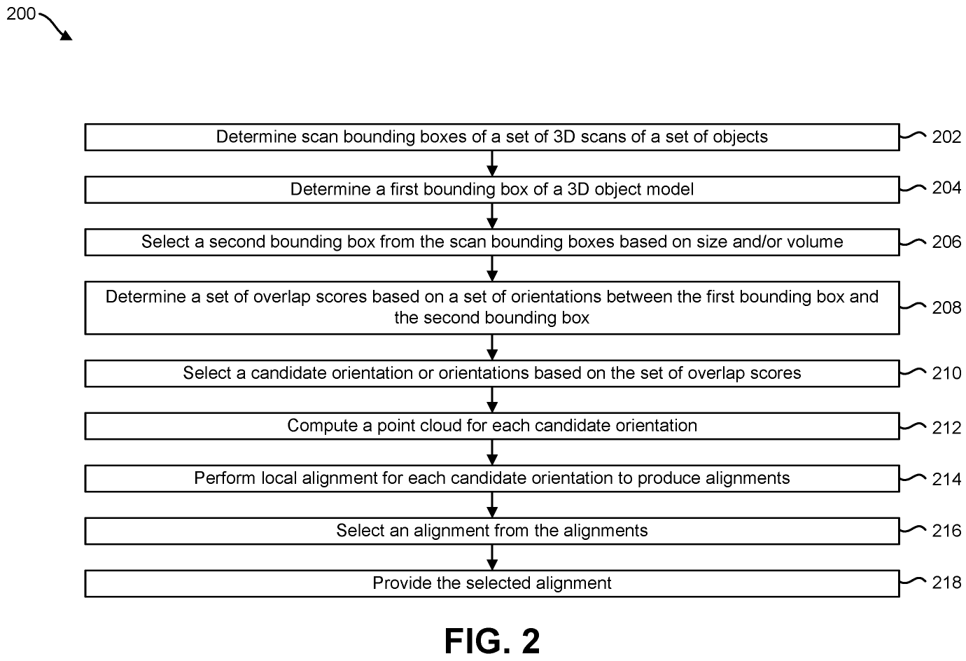

FIG. 2 is a flow diagram illustrating another example of a method 200 for registering objects. The method 200 and/or an element or elements of the method 200 may be performed by an apparatus (e.g., electronic device). For example, the method 200 may be performed by the apparatus 302 described in connection with FIG. 3.

The apparatus may determine 202 scan bounding boxes of a set of 3D scans of a set of objects. A scan bounding box is a bounding box of a scan of an object. In some examples, determining 202 the scan bounding boxes may be performed as described in relation to FIG. 1. For instance, the apparatus may determine a bounding box (e.g., minimum bounding box) for each of a set of 3D scans. In some examples, the scanned object or objects may be objects that were manufactured (e.g., 3D printed). The manufactured objects may correspond to 3D object models. In some examples, the set of 3D scans may be scans of different types of objects. For instance, the set of 3D scans may include scans of different objects corresponding to different 3D object models.

The apparatus may determine 204 a first bounding box of a 3D object model. In some examples, the apparatus may determine 204 the first bounding box (e.g., minimum bounding box) of the 3D object model as described in relation to FIG. 1.

The apparatus may select 206 a second bounding box from the scan bounding boxes based on a size and/or volume. For example, the apparatus may select 206 a second bounding box (or second bounding boxes) that satisfies a criterion or criteria based on size or volume. The criterion or criteria may enable selecting a second bounding box (or boxes) that is (or are) likely to enclose a same type of object as the 3D object model. Selecting 206 the second bounding box based on a size and/or volume may be beneficial by selecting a second bounding box (or boxes) that likely corresponds to a same object type and/or by eliminating a bounding box (or boxes) that likely correspond to a different object type.

In some examples, the apparatus may select 206 a second bounding box based on a volume percentage difference threshold. For instance, the apparatus may determine a volume percentage difference between the first bounding box of the 3D object model and a bounding box of a scan. In some examples, the volume percentage difference may be calculated by determining a volume percentage of the bounding box of the scan relative to a volume of the first bounding box. The apparatus may determine the volume percentage difference by calculating a difference (e.g., subtraction) of the volume percentage of the bounding box of the scan and the percentage (e.g., 100%) of the first bounding box. The apparatus may compare the volume percentage difference to the volume percentage difference threshold. A bounding box may be selected in a case that the volume percentage difference is within (e.g., is less than or equal to, is at most, is not greater than) the volume percentage difference threshold (e.g., 5%, 10%, 15%, 17%, 20%, etc.). With a volume percentage difference threshold of 15%, for instance, a bounding box may be selected if the bounding box is between 85% and 115% of the volume of the first bounding box. A bounding box of a scan may not be selected (and/or may be discarded) in a case that the volume percentage difference is not within (e.g., is greater than) the volume percentage difference threshold (e.g., 5%, 10%, 15%, 17%, 20%, etc.).

In some examples, the apparatus may select 206 a second bounding box based on a size difference threshold. For instance, dimensional size (e.g., length, width, height, area, edge, etc.) difference(s) between a bounding box of a scan and the first bounding box may be utilized and/or a dimensional size difference threshold(s) for a dimension or dimensions may be utilized. For instance, a bounding box of a scan may be selected in a case that a dimensional size difference is within a dimensional size difference threshold (for the X dimension, Y dimension, Z dimension, an edge dimension, and/or a face dimension of the bounding box, etc.). Otherwise, the bounding box may not be selected and/or may be discarded.

The apparatus may determine 208 a set of overlap scores based on a set of orientations between the first bounding box and the second bounding box. In some examples, determining 208 the set of overlap scores may be accomplished as described in relation to FIG. 1. For instance, the apparatus may rotate the second bounding box (or second bounding boxes) to the set of orientations and determine an overlap score for each orientation.

The apparatus may select 210 a candidate orientation or orientations based on the set of overlap scores. In some examples, selecting 210 a candidate orientation or orientations may be accomplished as described in relation to FIG. 1. For instance, the apparatus may select 210 a candidate orientation or orientations with an overlap score that is greater than or equal to a threshold. In some examples, the apparatus may select 210 a candidate orientation with a greatest overlap score in the set of overlap scores and/or an orientation or orientations with a next greatest overlap score or overlap scores.

The apparatus may compute 212 a point cloud for each candidate orientation. For example, the apparatus may compute a point cloud for a selected candidate orientation or selected candidate orientations. In some examples, the apparatus may compute 212 a point cloud over the surface of an object (e.g., scan) for each of the selected candidate orientations. In some examples, the density of the computed 212 point cloud may be greater than the density of an original scan (e.g., point cloud) of an object. For example, the original scan may have a density of 10,000 points and the density of the computed 212 point cloud may have a density of 100,000. Other density differences or ratios may be utilized. A greater density point cloud may help increase accuracy in local alignment.

The apparatus may perform 214 local alignment for each candidate orientation to produce alignments. In some examples, performing 214 local alignment for each candidate orientation may include performing an ICP procedure for each selected candidate orientation. The ICP procedure may produce an alignment or alignments. An alignment is an indication of a relative position (e.g., transformation, rotation, etc.) between objects (e.g., 3D object model, point cloud, scan, etc.). An alignment may have a corresponding alignment score. An alignment score is a value that indicates a degree of alignment between objects or a degree of overlap between objects.

In some examples, performing the ICP procedure may include performing a two-stage ICP refinement for each selected candidate orientation. In a first stage, the apparatus may refine a candidate orientation or orientations by applying a first set of ICP rounds. Each ICP round may include a different coarse voxel proximity threshold (e.g., 1.5, 2, 3, and 4 times a voxel size). For each voxel proximity threshold, the apparatus may create an object that is transformed by a corresponding ICP round. In a second stage, the apparatus may refine the alignments obtained from the first stage by applying a second set of ICP rounds. Each ICP round may have a different fine voxel proximity threshold (e.g., 0.125, 0.25, 0.5 and 0.75 times the voxel size). For instance, the voxel proximity thresholds of the second stage may be less than (e.g., smaller than) the voxel proximity thresholds for the first stage. For each voxel proximity threshold, the apparatus may create an object that is transformed by a corresponding ICP round. The second stage may produce alignments. For example, the second stage may produce point clouds or point cloud pairs (e.g., 16 point cloud pairs) with an alignment score for each orientation candidate (e.g., selected orientation candidate). The alignment score may indicate an amount of overlap between the 3D object model and the scan (e.g., increased density point cloud, scanned object, etc.) In some examples, the apparatus may sort the alignments by alignment score.

The apparatus may select 216 an alignment from the alignments. For example, the apparatus may select an alignment with a greatest alignment score. In some examples, if multiple alignments share the same alignment score, the apparatus may select an alignment with minimum second stage proximity thresholds and/or with maximum first stage proximity thresholds.

The apparatus may provide 218 the selected alignment. In some examples, providing 218 the selected alignment may be performed as described in relation to FIG. 1. For example, providing the registered 3D scan and 3D object model may include providing the 3D scan and the 3D object model aligned in accordance with the selected alignment. For instance, the apparatus may store the registered 3D scan and 3D object model, may send the registered 3D scan and 3D object model to another device, and/or may present the registered 3D scan and 3D object model (on a display and/or in a user interface, for example). In some examples, the apparatus may assess deformation using the registered 3D scan and 3D object model and/or may train a machine learning model based on the registered 3D scan and 3D object model. In some examples, operation(s), function(s), and/or element(s) of the method 200 may be omitted and/or combined.

FIG. 3 is a block diagram of an example of an apparatus 302 that may be used in registering objects. The apparatus 302 may be a computing device, such as a personal computer, a server computer, a printer, a 3D printer, a smartphone, a tablet computer, etc. The apparatus 302 may include and/or may be coupled to a processor 304, and/or a memory 306. In some examples, the apparatus 302 may be in communication with (e.g., coupled to, have a communication link with) an additive manufacturing device (e.g., a 3D printing device). In some examples, the apparatus 302 may be an example of a 3D printing device. The apparatus 302 may include additional components (not shown) and/or some of the components described herein may be removed and/or modified without departing from the scope of this disclosure.

The processor 304 may be any of a central processing unit (CPU), a semiconductor-based microprocessor, graphics processing unit (GPU), field-programmable gate array (FPGA), an application-specific integrated circuit (ASIC), and/or other hardware device suitable for retrieval and execution of instructions stored in the memory 306. The processor 304 may fetch, decode, and/or execute instructions (e.g., registration instructions 310) stored in the memory 306. In some examples, the processor 304 may include an electronic circuit or circuits that include electronic components for performing a functionality or functionalities of the instructions (e.g., registration instructions 310). In some examples, the processor 304 may perform one, some, or all of the functions, operations, elements, methods, etc., described in connection with one, some, or all of FIGS. 1-6C.

The memory 306 may be any electronic, magnetic, optical, or other physical storage device that contains or stores electronic information (e.g., instructions and/or data). Thus, the memory 306 may be, for example, Random Access Memory (RAM), Electrically Erasable Programmable Read-Only Memory (EEPROM), a storage device, an optical disc, and the like. In some implementations, the memory 306 may be a non-transitory tangible machine-readable storage medium, where the term “non-transitory” does not encompass transitory propagating signals.

In some examples, the apparatus 302 may also include a data store (not shown) on which the processor 304 may store information. The data store may be volatile and/or non-volatile memory, such as Dynamic Random Access Memory (DRAM), EEPROM, magnetoresistive random-access memory (MRAM), phase change RAM (PCRAM), memristor, flash memory, and the like. In some examples, the memory 306 may be included in the data store. In some examples, the memory 306 may be separate from the data store. In some approaches, the data store may store similar instructions and/or data as that stored by the memory 306. For example, the data store may be non-volatile memory and the memory 306 may be volatile memory.

In some examples, the apparatus 302 may include an input/output interface (not shown) through which the processor 304 may communicate with an external device or devices (not shown), for instance, to receive and store the information pertaining to the objects to be registered. The input/output interface may include hardware and/or machine-readable instructions to enable the processor 304 to communicate with the external device or devices. The input/output interface may enable a wired or wireless connection to the external device or devices. In some examples, the input/output interface may further include a network interface card and/or may also include hardware and/or machine-readable instructions to enable the processor 304 to communicate with various input and/or output devices, such as a keyboard, a mouse, a display, another apparatus, electronic device, computing device, etc., through which a user may input instructions into the apparatus 302. In some examples, the apparatus 302 may receive 3D model data 308 and/or scan data 316 from an external device or devices (e.g., 3D scanner, removable storage, network device, etc.).

In some examples, the memory 306 may store 3D model data 308. The 3D model data 308 may be generated by the apparatus 302 and/or received from another device. Some examples of 3D model data 308 include a 3MF file or files, a 3D computer-aided drafting (CAD) image, object shape data, mesh data, geometry data, point cloud data, etc. The 3D model data 308 may indicate the shape an object or objects.

In some examples, the memory 306 may store scan data 316. The scan data 316 may be generated by the apparatus 302 and/or received from another device. Some examples of scan data 316 include object shape data, mesh data, geometry data, point cloud data, depth map data, etc. The scan data 316 may indicate the shape of an object or objects that have been manufactured (e.g., printed).

The memory 306 may store registration instructions 310. The processor 304 may execute the registration instructions 310 to register objects. For instance, the processor 304 may execute the registration instructions 310 to register a 3D object model with a 3D scan of an object. The 3D object model may be stored as and/or represented by the 3D model data 308, for instance. The 3D scan may be stored as and/or represented by the scan data 316, for instance.

In some examples, the processor 304 may execute the registration instructions 310 to compare a first size of a first bounding box of a 3D object model to sizes of a set of bounding boxes of scanned objects. In some examples, this may be accomplished as described in connection with FIG. 2. For instance, the processor 304 may compare a volume or dimensional size of the first bounding box with volumes or dimensional sizes of a set of bounding boxes of scanned objects. For instance, the first size of the first bounding box may be a first volume of the first bounding box and the sizes of the set of bounding boxes may be volumes of the set of bounding boxes. In some examples, the processor 304 may compare the first volume to the volumes by determining whether each of the volumes is within a threshold range of the first volume. The processor 304 may remove a bounding box or bounding boxes from the set of bounding boxes based on the comparison. For instance, a bounding box or bounding boxes that are beyond a threshold difference in size from the first bounding box may be removed.

In some examples, the processor 304 may execute the registration instructions 310 to orient each bounding box of the set of bounding boxes relative to the first bounding box using a set of orientations to calculate a set of overlap scores. In some examples, this may be accomplished as described in connection with FIG. 1 and/or FIG. 2.

In some examples, the processor 304 may execute the registration instructions 310 to select a candidate orientation from the set of orientations based on the set of overlap scores. In some examples, this may be accomplished as described in connection with FIG. 1 and/or FIG. 2.

In some examples, the processor 304 may execute the operation instructions 318 to perform an operation based on the selected candidate registration. For example, the processor 304 may present the selected candidate registration and/or an alignment based on the selected candidate registration on a display, may store the selected candidate registration in the memory 306, and/or may send the selected candidate registration to another device or devices. In some examples, the processor 304 may assess a deformation of an object based on the selected candidate orientation and/or may train a machine learning model based on the selected candidate orientation. In some examples, the processor 304 may manufacture (e.g., print) an object or objects based on the selected candidate orientation. For instance, the processor 304 may drive model setting based on a deformation-compensated 3D model that is based on the selected candidate orientation.

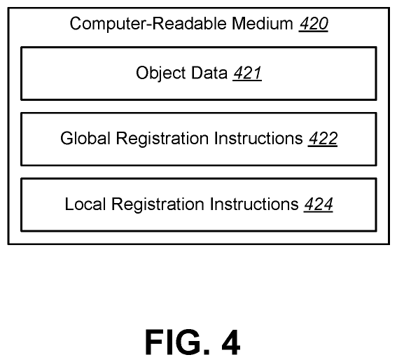

FIG. 4 is a block diagram illustrating an example of a computer-readable medium 420 for registering objects. The computer-readable medium 420 may be a non-transitory, tangible computer-readable medium 420. The computer-readable medium 420 may be, for example, RAM, EEPROM, a storage device, an optical disc, and the like. In some examples, the computer-readable medium 420 may be volatile and/or non-volatile memory, such as DRAM, EEPROM, MRAM, PCRAM, memristor, flash memory, and the like. In some implementations, the memory 306 described in connection with FIG. 3 may be an example of the computer-readable medium 420 described in connection with FIG. 4.

The computer-readable medium 420 may include code (e.g., data and/or instructions). For example, the computer-readable medium 420 may include object data 421, global registration instructions 422, and/or local registration instructions 424.

In some examples, the computer-readable medium 420 may store object data 421. Some examples of object data 421 include a 3MF file or files, a 3D CAD file, object shape data, point cloud data, scan data, mesh data, geometry data, etc. The object data 421 may indicate the shape of a 3D object model and/or scans of 3D objects.

In some examples, the global registration instructions 422 are code to cause a processor to perform a global registration between a first bounding box of a 3D object model and a second bounding box of a 3D scan of an object using a set of orientations. In some examples, this may be accomplished as described in connection with FIG. 1, FIG. 2, and/or FIG. 3. A global registration is a registration that produces a selected candidate orientation for a set of orientations.

In some examples, the local registration instructions 424 are code to cause the processor to perform a local registration of a point cloud of the object and the 3D object model based on the global registration. In some examples, this may be accomplished as described in relation to FIG. 1, FIG. 2, and/or FIG. 3. For instance, the local registration instructions may cause a processor to perform an ICP procedure (e.g., a two-stage ICP procedure). The local registration may produce a selected alignment between the point cloud of the object and the 3D object model. In some examples, the point cloud may have a greater density than the 3D scan.

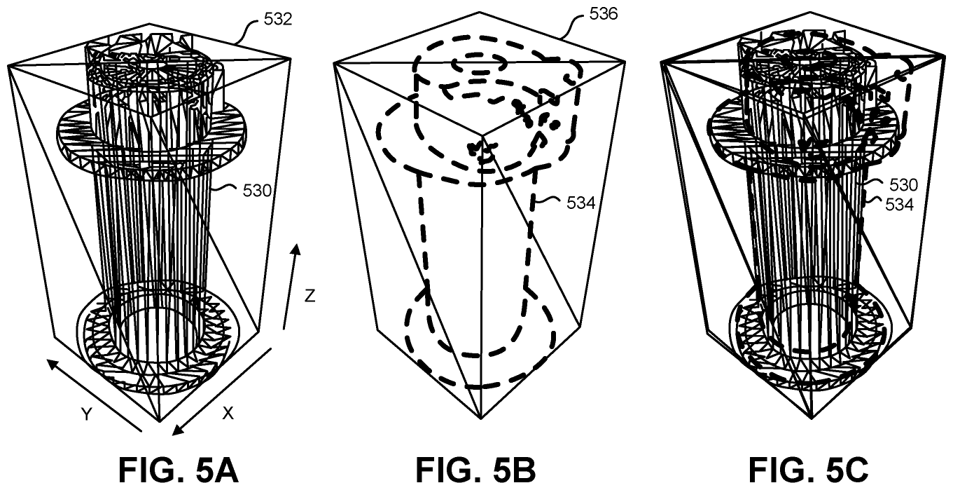

FIG. 5A is a diagram illustrating an example of a 3D object model 530. FIG. 5A illustrates the 3D object model 530 enclosed by a bounding box 532 in accordance with some examples of the techniques described herein.

FIG. 5B is a diagram illustrating an example of a 3D scan 534 of an object. FIG. 5B illustrates the 3D scan 534 (e.g., point cloud) enclosed by a bounding box 536 in accordance with some examples of the techniques described herein.

FIG. 5C is a diagram illustrating an example of a 3D object model 530 from FIG. 5A overlapped with the scan 534 of the 3D object from FIG. 5B. In FIG. 5C, the scan 534 and/or the corresponding bounding box 536 may be selected (based on volume percentage difference, for instance). In FIG. 5C, the scan 534 may be rotated 0 degrees in X and 0 degrees in Y (e.g., may be situated at a base rotation). Some examples of the techniques described herein may be utilized to perform the registration between the 3D object model 530 and the 3D scan 534 of the object.

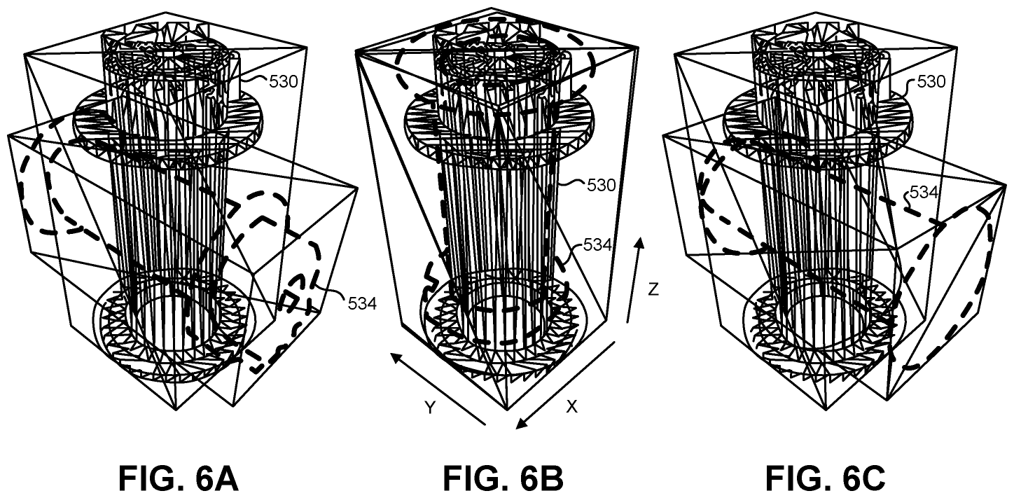

FIG. 6A is a diagram illustrating an example of the scan 534 of the 3D object from FIG. 5B at an orientation relative to the 3D object model 530 from FIG. 5A. In this example, the scan 534 from FIG. 5B is rotated 90 degrees in the Y axis.

FIG. 6B is a diagram illustrating an example of the scan 534 of the 3D object from FIG. 5B at an orientation relative to the 3D object model 530 from FIG. 5A. In this example, the scan 534 from FIG. 5B is rotated 180 degrees in the Y axis.

FIG. 6C is a diagram illustrating an example of the scan 534 of the 3D object from FIG. 5B at an orientation relative to the 3D object model 530 from FIG. 5A. In this example, the scan 534 from FIG. 5B is rotated 270 degrees in the Y axis and 90 degrees in the Z axis. The orientations (e.g., bounding box rotations) described in relation to FIGS. 6A, 6B, and 6C may be examples of orientations in the set of orientations utilized to determine overlap scores in accordance with some examples of the techniques described herein. For instance, the 3D object model 530 and the scan 534 (with corresponding bounding boxes 532, 536) may be translated to match their centroids with a set of rotations. In some examples, the orientations illustrated in FIG. 6A and FIG. 6C may be discarded and/or not selected due to intersection ratios below a threshold (e.g., 95%). In some examples, the orientations illustrated in FIG. 5C and FIG. 6B may be selected as candidate orientations due to intersection ratios above a threshold (e.g., 95%).

Some examples of the techniques described herein provide approaches for 3D registration that utilize bounding boxes (e.g., minimum bounding boxes) for object orientation. In 3D printing, many (e.g., hundreds) of objects may be packed into a build volume. The build volume may have a corresponding file (e.g., 3MF file) that indicates the position and orientation of each object in the build volume. When the build volume is printed, the objects in the build volume may be printed together. After printing, each object may be removed from the build volume for cleaning and/or post-processing. These procedures may result in untraceable transformations (e.g., translation and/or rotation) of objects relative to the original object positions and/or orientations in the build volume.

A printed object or objects may be scanned to produce a point cloud (e.g., scanned 3D file) that represents the shape of the printed object(s). To evaluate the geometrical accuracy of the print, the point cloud may be compared with the original CAD file to generate a deformation assessment. The 3D information (e.g., the CAD file and point clouds) may be aligned to recover the transformation that the printed object or objects have undergone. Aligning the object and the scan may be challenging because the search space of the transformation may be very large.

Some approaches for 3D registration may include downsampling point clouds, extracting a feature histogram (e.g., Fast Point Feature Histogram (FPFH)) descriptor of each point, picking random points in the source cloud, and detecting corresponding points in the target cloud by querying nearest neighbors in the FPFH feature space. The source cloud may be transformed iteratively to provide a rough alignment of the down sample point clouds. A shortcoming of these approaches is the randomized selection of the points: the results depend on the quality of the randomized selection, which may vary.

Some examples of the techniques described herein may provide beneficial approaches for accurate and efficient object registration. Some examples may provide approaches for deterministic 3D registration. Deterministic 3D registration may identify 3D object model (e.g., CAD model) and scan pairs regardless of initial position (e.g., rotation and translation). Deterministic registration may be utilized to obtain a set of transformation matrices (where the same results may be obtained for a given 3D object model and scan with particular positions). In some examples, the transformation matrices may be later directly applied to models and/or scans without the need to perform the procedure repeatedly. In some examples of deterministic 3D registration, for instance, an initial volume and/or size verification of the objects may be performed to discard non-comparable objects or models. A global registration may be performed based on minimum bounding boxes of the objects to provide a rough initialization. A two-stage refinement procedure (e.g., ICP refinement) may be performed by varying a correspondence proximity parameter to get accurate results.

While various examples of systems and methods are described herein, the systems and methods are not limited to the examples. Variations of the examples described herein may be implemented within the scope of the disclosure. For example, operations, functions, aspects, or elements of the examples described herein may be omitted or combined.

1. A method, comprising:
determining a set of overlap scores based on a set of orientations between a first bounding box of a three-dimensional (3D) object model and a second bounding box of a 3D scan of an object; and
registering the 3D scan with the 3D object model based on the set of overlap scores.

2. The method of claim 1, wherein determining the overlap scores comprises calculating an intersection ratio for each of the set of orientations.

3. The method of claim 1, wherein the set of orientations comprises orthogonal angle rotations for an axis or axes.

4. The method of claim 1, further comprising determining the first bounding box of the 3D object model.

5. The method of claim 1, further comprising determining scan bounding boxes of a set of 3D scans of a set of objects.

6. The method of claim 5, further comprising selecting the second bounding box from the scan bounding boxes based on a size or volume.

7. The method of claim 1, wherein registering the 3D scan with the 3D object model comprises selecting a candidate orientation based on the set of overlap scores.

8. The method of claim 7, wherein registering the 3D scan with the 3D object model comprises computing a point cloud for the candidate orientation.

9. The method of claim 8, wherein registering the 3D scan with the 3D object model comprises performing local alignment for the candidate orientation to produce alignments.

10. The method of claim 9, wherein registering the 3D scan with the 3D object model comprises selecting an alignment from the alignments.

11. An apparatus, comprising:
a memory;
a processor in electronic communication with the memory, wherein the processor is to:
compare a first size of a first bounding box of a three-dimensional object model to sizes of a set of bounding boxes of scanned objects;
remove a bounding box from the set of bounding boxes based on the comparison;
orient each bounding box of the set of bounding boxes relative to the first bounding box using a set of orientations to calculate a set of overlap scores; and
select a candidate orientation from the set of orientations based on the set of overlap scores.

12. The apparatus of claim 11, wherein the first size of the first bounding box is a first volume of the first bounding box and the sizes of the set of bounding boxes are volumes of the set of bounding boxes.

13. The apparatus of claim 12, wherein the processor is to compare the first volume to the volumes by determining whether each of the volumes is within a threshold range of the first volume.

14. A non-transitory tangible computer-readable medium storing executable code, comprising:
code to cause a processor to perform a global registration between a first bounding box of a three-dimensional (3D) object model and a second bounding box of a 3D scan of an object using a set of orientations; and
code to cause the processor to perform a local registration of a point cloud of the object and the 3D object model based on the global registration.

15. The computer-readable medium of claim 14, wherein the point cloud has a greater density than the 3D scan.
